(19) United States
(12) Patent Application Publication
(10) Pub. No.: US 2026/0370213 A1
(43) Pub. Date: Nov. 19, 2026

(54) PIEZOELECTRIC RESONATOR

(71) Applicant: Murata Manufacturing Co., Ltd., Nagaokakyo-shi (JP)

(72) Inventor: Kei ISHII, Nagaokakyo-shi (JP)

(21) Appl. No.: 19/728,423

(22) Filed: Jul. 2, 2026

Related U.S. Application Data
(63) Continuation of application No. PCT/JP2025/003818, filed on Feb. 5, 2025.

(30) Foreign Application Priority Data
Mar. 12, 2024 (JP) 2024-038000

(51) Int. Cl. H03H 9/13; H03H 9/10; H03H 9/19

(52) U.S. Cl. CPC H03H 9/131; H03H 9/1021; H03H 9/19

(57) ABSTRACT

A piezoelectric resonator that includes: a piezoelectric element; and an excitation electrode disposed on or over a major face of the piezoelectric element. The excitation electrode includes: a first metal layer disposed on or over the piezoelectric element; and a second metal layer disposed on or over a side of the first metal layer opposite from the piezoelectric element. The second metal layer is made of a material that is more resistant to oxidation than the material of the first metal layer. At the surface of the excitation electrode, the elemental ratio of an element constituting the second metal layer is greater than or equal to 99.5% and less than or equal to 100%.

### CROSS REFERENCE TO RELATED APPLICATIONS

The present application is a continuation of International application No. PCT/JP2025/003818, filed Feb. 5, 2025, which claims priority to Japanese Patent Application No. 2024-038000, filed Mar. 12, 2024, the entire contents of each of which are incorporated herein by reference.

### TECHNICAL FIELD

The present disclosure relates to a piezoelectric resonator.

### BACKGROUND ART

Piezoelectric resonators are used in various electronic equipment, including mobile communication terminals, communication base stations, and household electrical appliances, for applications such as timing devices, sensors, or oscillators. Such a piezoelectric resonator includes a piezoelectric element having a pair of major faces, and a pair of excitation electrodes disposed on the pair of major faces of the piezoelectric element.

For example, Patent Document 1 discloses a resonant element. The resonant element has a piezoelectric substrate, and an electrode layer disposed on the piezoelectric substrate. The electrode layer includes a layer of oxidizable material stacked on the piezoelectric substrate, and a layer of noble metal material stacked on the oxidizable material layer. In adjusting the frequency of the resonant element, oxidation is performed to cause the oxidizable material to diffuse into the noble metal layer, and the oxidizable material that has become exposed on the surface of the electrode layer is oxidized.

Patent Document 1: Japanese Unexamined Patent Application Publication No. 2014-200040

### SUMMARY OF THE DISCLOSURE

A potential issue with the resonant element described in Patent Document 1 is that, even after the frequency adjustment, an unoxidized oxidizable material may continue to diffuse into the noble metal layer. As the material becomes exposed on the surface of the electrode layer and oxidizes, this may cause a change in frequency.

In view of the circumstances mentioned above, the present disclosure is directed to providing a piezoelectric resonator configured to reduce frequency drift.

A piezoelectric resonator according to an aspect of the present disclosure includes: a piezoelectric element; and an excitation electrode disposed on or over a major face of the piezoelectric element. The excitation electrode includes: a first metal layer disposed on or over the piezoelectric element; and a second metal layer disposed on or over a side of the first metal layer opposite from the piezoelectric element. The second metal layer is made of a material that is more resistant to oxidation than a material of the first metal layer. At a surface of the excitation electrode, an elemental ratio of an element constituting the second metal layer is greater than or equal to 99.5% and less than or equal to 100%.

The present disclosure makes it possible to provide a piezoelectric resonator configured to reduce frequency drift.

### BRIEF DESCRIPTION OF THE DRAWINGS

FIG. 1 is an exploded perspective view of a quartz crystal resonator unit according to a first embodiment.

FIG. 2 is a cross-sectional view of the quartz crystal resonator unit according to the first embodiment.

FIG. 3 is a cross-sectional view of a quartz crystal resonator according to the first embodiment.

FIG. 4 is an SEM image of an excitation electrode surface according to an example.

FIG. 5 is an SEM image of an excitation electrode surface according to a comparative example.

FIG. 6 is a graph representing the XPS measurements of an excitation electrode surface according to an example.

FIG. 7 is a graph representing the XPS measurements of an excitation electrode surface according to a comparative example.

FIG. 8 is a graph representing the XPS measurements of an excitation electrode surface according to a comparative example.

FIG. 9 is a graph representing frequency drift in a damp heat environment according to an example.

FIG. 10 is a graph representing frequency drift in a damp heat environment according to a comparative example.

FIG. 11 is a graph representing frequency drift in a damp heat environment according to a comparative example.

FIG. 12 is a graph representing variations in frequency drift rate in a damp heat environment.

FIG. 13 is a graph representing the XPS measurements of an excitation electrode surface.

FIG. 14 is a graph representing the XPS measurements of an excitation electrode surface.

FIG. 15 is a graph representing the XPS measurements of an excitation electrode surface.

FIG. 16 is a graph representing the XPS measurements of an excitation electrode surface.

FIG. 17 is a graph representing the XPS measurements of an excitation electrode surface.

FIG. 18 is a graph representing the XPS measurements of an excitation electrode surface.

FIG. 19 is a graph representing the XPS measurements of an excitation electrode surface.

FIG. 20 is a graph representing the XPS measurements of an excitation electrode surface.

### DESCRIPTION OF THE PREFERRED EMBODIMENTS

Embodiments of the present disclosure will now be described. In the following description of the drawings, identical or similar structural elements are designated by identical or similar reference signs. The drawings are illustrative only, and the illustrated dimensions, shapes, or other features of individual components or parts are schematic in nature and not to be construed as limiting the technical scope of the present disclosure to the embodiments.

For convenience, the drawings may be accompanied by an orthogonal coordinate system including an X axis, a Y′ axis, and a Z′ axis to clarify the relationship between the drawings and to aid in understanding the positional relationship between individual members or components. The X axis, the Y′ axis, and the Z′ axis are consistent throughout the drawings. The X axis, the Y′ axis, and the Z′ axis correspond to the crystallographic axes of a quartz crystal element 11, which will be described later. The X axis, a Y axis, and a Z axis correspond to the electrical axis (polar axis), the mechanical axis, and the optical axis, respectively, of a quartz crystal. As viewed in the positive X axis direction, the Y′ axis and Z′ axis are respectively derived by rotating the Y axis and the Z axis counterclockwise around the X axis by θ degrees.

In the following description, a direction parallel to the X axis will be referred to as an “X axis direction”, a direction parallel to the Y′ axis will be referred to as a “Y′ axis direction”, and a direction parallel to the Z′ axis will be referred to as a “Z′ axis direction”. Further, the direction pointed to by the tip of each of the arrows representing the X axis, the Y′ axis, and the Z′ axis will be referred to as “positive” or “+(plus)”, and the direction opposite to that pointed to by the arrow will be referred to as “negative” or “− (minus)”. For convenience, the +Y′ axis direction will be referred to as upward, and the −Y′ axis direction will be referred to as downward. This, however, is not intended to limit the upward and downward directions of a quartz crystal resonator 10 and a quartz crystal resonator unit 1. Further, the plane defined by the X axis and the Z′ axis will be referred to as a Z′X plane, and the same applies to planes defined by other axes.

### First Embodiment

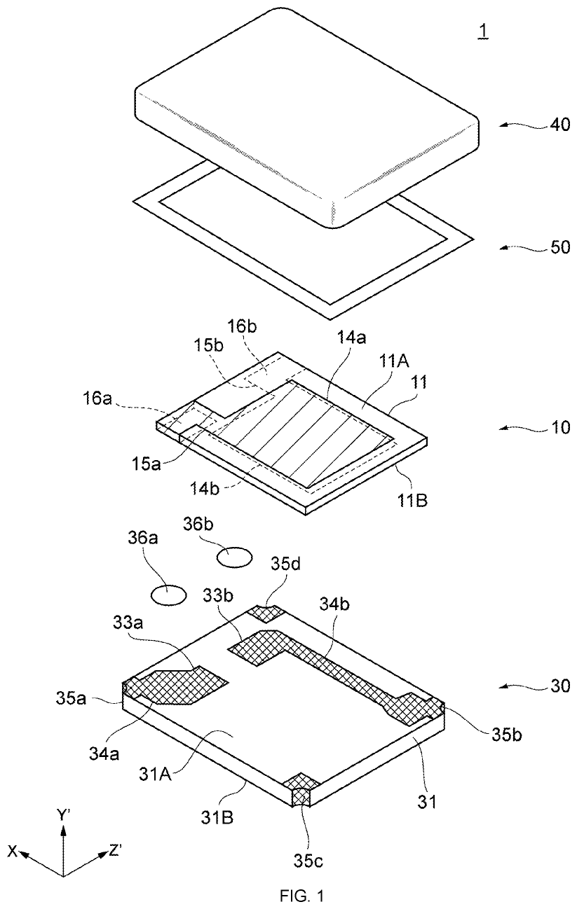

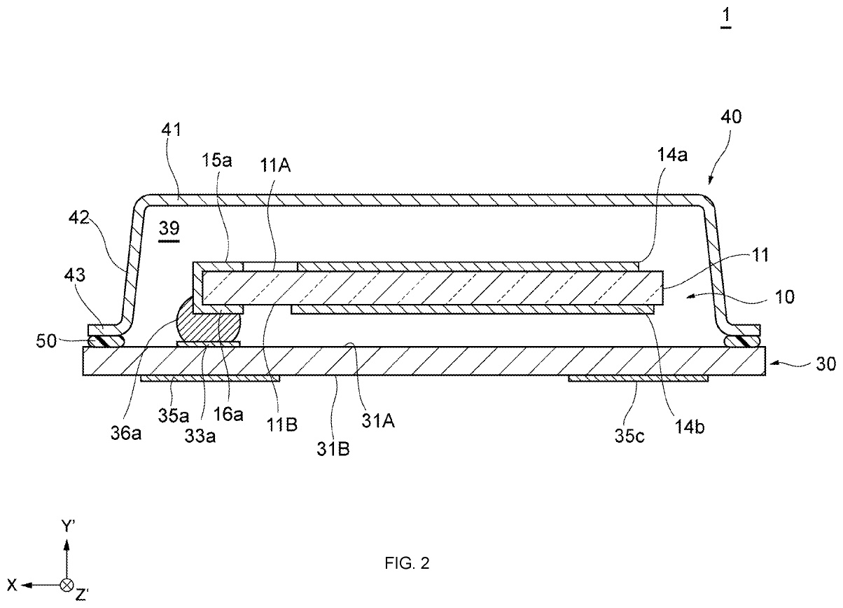

First, the configuration of a quartz crystal resonator unit according to a first embodiment will be described with reference to FIGS. 1 and 2. FIG. 1 is an exploded perspective view of the quartz crystal resonator unit according to the first embodiment. FIG. 2 is a cross-sectional view of the quartz crystal resonator unit according to the first embodiment.

The quartz crystal resonator unit 1 includes the quartz crystal resonator 10, a base member 30, a lid member 40, and a bond 50. Hereinafter, the Y′ axis direction will be referred to as the “thickness direction” of the quartz crystal resonator 10.

The quartz crystal resonator unit 1 is used as, for example, a component in an oscillator such as a temperature compensated crystal oscillator (TCXO), a voltage controlled crystal oscillator (VCXO), or an oven controlled crystal oscillator (OCXO).

The quartz crystal resonator 10 is an electromechanical energy converter configured to convert between electrical energy and mechanical energy through the piezoelectric effect.

The quartz crystal resonator 10 is excited at a predetermined frequency based on an applied alternating voltage. The quartz crystal resonator 10 is secured in place in a manner that allows it to vibrate within a vibration space defined between the base member 30 and the lid member 40. The primary vibration mode of the quartz crystal resonator 10 is the thickness shear vibration mode.

The primary vibration mode of the quartz crystal resonator is not limited to the thickness shear vibration mode. Alternatively, the primary vibration mode may be, for example, the thickness extensional vibration mode, the contour extensional vibration mode, the longitudinal vibration mode, or the flexural vibration mode.

As illustrated in FIG. 1, the quartz crystal resonator 10 includes the following components: the quartz crystal element 11 in the form of a thin element; a first excitation electrode 14a and a second excitation electrode 14b, which constitute a pair of excitation electrodes; a first extended electrode 15a and a second extended electrode 15b, which constitute a pair of extended electrodes; and a first connection electrode 16a and a second connection electrode 16b, which constitute a pair of connection electrodes.

The quartz crystal element 11 has an upper face 11A and a lower face 11B, which are opposite to each other. The upper face 11A is located at the side facing a top wall 41 (described later) of the lid member 40. The lower face 11B is located at the side facing the base member 30. The upper face 11A and the lower face 11B correspond to a pair of major faces of the quartz crystal element 11.

The quartz crystal element 11 is, for example, an AT-cut quartz crystal element. An AT-cut quartz crystal element is formed such that the XZ′ plane is its major face and the direction parallel to the Y′ axis is its thickness. In one example, with the upper face 11A seen in plan view in the thickness direction (to be referred to simply as “in plan view” hereinafter), the quartz crystal element 11 has a shape (to be referred to as “plan-view shape” hereinafter) that is an oblong rectangle with a pair of short sides extending in the Z′ axis direction and a pair of long sides extending in the X axis direction. In one example, the quartz crystal element 11 has a flat shape with a uniform thickness.

The plan-view shape of the quartz crystal element is not limited to that mentioned above. For example, the plan-view shape of the quartz crystal element may be an oblong rectangle with long sides extending in the Z′ axis direction and short sides extending in the X axis direction, or a square with sides extending in the Z′ axis direction and sides extending in the X axis direction. The plan-view shape of the quartz crystal element may also be a rectangle with sides extending in a direction intersecting with the X axis direction and the Z′ axis direction. The plan-view shape of the quartz crystal element may be a polygon, a circle, an ellipse, or a combination of these shapes. The shape of the quartz crystal element is not limited to a flat shape. The quartz crystal element may have a mesa structure or an inverted mesa structure in which at least one of the upper face or the lower face has projections and depressions. The quartz crystal element may have a convex structure in which its thickness varies in a continuous fashion, or may have a beveled structure in which its thickness varies in a discontinuous fashion.

The quartz crystal element 11 with the AT-cut is cut out with an XZ′ plane as a major face from a synthetic quartz crystal having X-, Y-, and Z-axes as crystallographic axes, of which the Y axis and the Z axis are rotated about the X axis by 35 degrees 15 minutes±1 minute 30 seconds in a direction from the Y axis toward the Z axis to define the Y′ axis and the Z′ axis.

The quartz crystal resonator 10 employing the quartz crystal element 11 with the AT-cut has high frequency stability over a wide temperature range. Such an AT-cut quartz crystal resonator also has superior aging characteristics and can be manufactured at low cost. Further, such an AT-cut quartz crystal resonator utilizes the thickness shear vibration mode as its primary vibration mode.

With regard to the cut-angles of the quartz crystal element, the cut of the quartz crystal element is not limited to that mentioned above. The rotation angles of the Y′ and Z′ axes of the quartz crystal element 11 with the AT-cut may deviate from 35 degrees 15 minutes within a range from −5 degrees to +15 degrees. Further, with regard to the cut-angles of the quartz crystal element, a cut different from the AT-cut may be used, such as a BT-cut, a GT-cut, or an SC-cut. The primary vibration mode of the quartz crystal resonator is not limited to the thickness shear vibration mode. Alternatively, the primary vibration mode may be, for example, the thickness extensional vibration mode, the contour extensional vibration mode, the longitudinal vibration mode, or the flexural vibration mode.

The first excitation electrode 14a and the second excitation electrode 14b are configured to apply an alternating voltage to the quartz crystal element 11 to excite the quartz crystal element 11. The first excitation electrode 14a and the second excitation electrode 14b are disposed in the central portion of the quartz crystal element 11 in plan view. The first excitation electrode 14a is disposed on or over the upper face 11A, and the second excitation electrode 14b is disposed on or over the lower face 11B. The first excitation electrode 14a and the second excitation electrode 14b are located opposite to each other in the Y′ axis direction across the quartz crystal element 11.

The plan-view shape of the first excitation electrode 14a is an oblong rectangle with short sides extending in the Z′ axis direction and long sides extending in the X axis direction. The first excitation electrode 14a has a thickness in the Y′ axis direction. The second excitation electrode 14b has the same or similar shape.

The plan-view shape of each of the first and second excitation electrodes is not limited to that mentioned above. The plan-view shape of each of the first and second excitation electrodes may be an oblong rectangle with short sides extending in the X axis direction, or may be a square with sides extending in the X axis direction and sides extending in the Z′ axis direction. The plan-view shape of each of the first and second excitation electrodes may be a rectangle with sides extending in a direction intersecting with the X axis direction and with the Z′ axis direction. The plan-view shape of each of the first and second excitation electrodes may be a polygon, a circle, an ellipse, or a combination of these shapes.

The first extended electrode 15a electrically connects the first excitation electrode 14a and the first connection electrode 16a, and the second extended electrode 15b electrically connects the second excitation electrode 14b and the second connection electrode 16b. The first extended electrode 15a is disposed so as to extend from the upper face 11A to the lower face 11B of the quartz crystal element 11, and the second extended electrode 15b is disposed on the lower face 11B of the quartz crystal element 11.

The first connection electrode 16a and the second connection electrode 16b electrically connect the quartz crystal resonator 10 to the base member 30. The first connection electrode 16a and the second connection electrode 16b are disposed on the lower face 11B of the quartz crystal element 11.

The first excitation electrode 14a, the first extended electrode 15a, and the first connection electrode 16a are provided integrally. The same applies to the second excitation electrode 14b, the second extended electrode 15b, and the second connection electrode 16b. A group of electrodes including the first excitation electrode 14a, the first extended electrode 15a, and the first connection electrode 16a is defined as a first electrode, and a group of electrodes including the second excitation electrode 14b, the second extended electrode 15b, and the second connection electrode 16b is defined as a second electrode.

The first electrode and the second electrode are of, for example, a multilayer structure including a base layer and a surface layer that are stacked in this order. The base layer is made of a metal material that provides better adhesion to the quartz crystal element 11 than does the material of the surface layer. The material of the base layer is, for example, chromium (Cr), a titanium-tungsten alloy (WTi), or an alloy containing these components. Preferably, the surface layer is made of a metal material that is more resistant to oxidation and more electrically conductive than is the material of the base layer. The material of the surface layer is, for example, gold (Au), platinum (Pt), palladium (Pd), iridium (Ir), rhodium (Rh), or an alloy containing these metals. The first electrode and the second electrode may contain titanium (Ti), aluminum (Al), molybdenum (Mo), or an aluminum-copper alloy (AlCu) including aluminum (Al) as its major component.

The base member 30 supports the quartz crystal resonator 10 in a manner that allows excitation of the quartz crystal resonator 10. The base member 30 includes a base 31, connection electrodes 33a and 33b, extended electrodes 34a and 34b, and outer electrodes 35a, 35b, 35c, and 35d.

The base 31 is a plate-shaped insulator having an upper face 31A and a lower face 31B that are opposite to each other in the thickness direction. The upper face 31A and the lower face 31B correspond to a pair of major faces of the base 31. The upper face 31A is located at the side facing the quartz crystal resonator 10 and the lid member 40, and corresponds to a mounting face to which the quartz crystal resonator 10 is to be mounted. The lower face 31B is located opposite to the upper face 31A, and corresponds to a connection face to which an external substrate is to be connected. To reduce thermal stress applied from the base 31 to the quartz crystal resonator 10 due to thermal history resulting from reflow or other processes, the base 31 is preferably made of a heat-resistant material. For a similar reason, the base 31 may be made of a material with a thermal expansion coefficient close to that of the quartz crystal element 11. The base 31 is provided as, for example, a ceramic substrate, a glass substrate, or a quartz crystal substrate.

The corner portions of the base 31 have a notched side face partially formed in a cylindrically curved shape (also referred to as a castellation shape). The shape of the corner portions of the base 31 is not limited to that mentioned above. The corner portions of the base may have a notched side face formed in a prismatic shape, or may be substantially right-angled corner portions without a notch.

The connection electrodes 33a and 33b are electrically connected to the quartz crystal resonator 10. The connection electrode 33a is electrically connected to the first connection electrode 16a of the quartz crystal resonator 10, and the connection electrode 33b is connected to the second connection electrode 16b of the quartz crystal resonator 10.

The extended electrode 34a electrically connects the connection electrode 33a and the outer electrode 35a, and the extended electrode 34b electrically connects the connection electrode 33b and the outer electrode 35b. The extended electrodes 34a and 34b are disposed on the upper face 31A of the base 31.

The outer electrodes 35a and 35b are external terminals for electrically connecting the quartz crystal resonator 10 to an external substrate (not illustrated). The outer electrode 35a electrically connects the first excitation electrode 14a of the quartz crystal resonator 10 to the external substrate, and the outer electrode 35b electrically connects the second excitation electrode 14b of the quartz crystal resonator 10 to the external substrate. One of the outer electrodes 35c and 35d is a grounding electrode that grounds the lid member 40, and the other is a dummy electrode that is electrically connected to neither the quartz crystal resonator 10 nor the lid member 40. The outer electrodes 35a, 35b, 35c, and 35d are each provided so as to extend continuously to the lower face 31B from the notched side face located at the corresponding one of the four corner portions of the base 31. In the example illustrated in FIG. 1, the outer electrodes 35a and 35b are located at one pair of diagonally opposite corners of the upper face 31A of the base 31, and the outer electrodes 35c and 35d are located at the other pair of diagonally opposite corners of the upper face 31A of the base 31.

The functions and positions of the outer electrodes 35a, 35b, 35c, and 35d are not limited to those described above. The outer electrodes 35c and 35d may be both grounding electrodes, or may be both dummy electrodes. The outer electrodes 35c and 35d may be omitted. The outer electrode 35c may be electrically connected to one of the outer electrodes 35a and 35b, and the outer electrode 35d may be electrically connected to the other of the outer electrodes 35a and 35b. In plan view, the outer electrodes 35a and 35b may be located at the same short side of the upper face 31A of the base 31, or may be located at the same long side of the upper face 31A of the base 31.

Conductive holding members 36a and 36b are disposed at a side of the base member 30 near the quartz crystal resonator 10. The conductive holding members 36a and 36b electrically connect the base member 30 and the quartz crystal resonator 10, and mechanically hold the quartz crystal resonator 10 in place. The conductive holding member 36a electrically connects the first connection electrode 16a of the quartz crystal resonator 10 to the connection electrode 33a of the base member 30. The conductive holding member 36b electrically connects the second connection electrode 16b of the quartz crystal resonator 10 to the connection electrode 33b of the base member 30. The conductive holding members 36a and 36b are each a cured product of a conductive adhesive containing a resin such as a thermosetting resin or a photo-curable resin. The major component of the conductive holding members 36a and 36b is, for example, a silicone resin. The conductive holding members 36a and 36b contain conductive particles, such as metal particles containing silver (Ag).

The major component of the conductive holding members 36a and 36b is not limited to a silicone resin, but may be, for example, an epoxy resin or an acrylic resin. The conductive particles contained in the conductive holding members 36a and 36b are not limited to silver particles, but may be made of materials such as other metals, conductive ceramic materials, or conductive organic materials. The conductive holding members 36a and 36b may contain a conductive polymer.

An internal space 39 is defined between the lid member 40 and the base member 30. The quartz crystal resonator 10 is accommodated in the internal space 39. The lid member 40 has the top wall 41, a side wall 42, which extends from the outer periphery of the top wall 41 toward the base member 30, and a flange 43, which extends outward from an end portion of the side wall 42 near the base member 30. The top wall 41 faces the base member 30 across the quartz crystal resonator 10 in the Y′ axis direction. The side wall 42 surrounds the quartz crystal resonator 10 with a spacing therebetween in the XZ′ plane direction. The flange 43, which is in the form of a frame in plan view, is a portion of the lid member 40 located closest to the base member 30. The lid member 40 is preferably made of a conductive material, and more preferably a hermetic metal material. Using a conductive material for the lid member 40 allows the lid member 40 to have an electromagnetic shielding capability to reduce the entry and exit of electromagnetic waves into and from the internal space 39. To reduce the generation of thermal stress, the lid member 40 is preferably made of a material with a thermal expansion coefficient close to that of the base member 30. An example of such a material is an Fe—Ni—Co alloy whose thermal expansion coefficient near room temperature matches those of glass and ceramic materials over a wide temperature range. The lid member 40 is electrically connected to at least one of the outer electrodes 35c and 35d by a grounding member (not illustrated).

The material of the lid member is not limited to a conductive material. The lid member may be made of an insulating material such as a ceramic material. This helps to ensure that an electrode extending across the bond provided on the major face of the base member is not electrically short-circuited through the lid member. This allows the bond to have a reduced thickness. When the lid member is made of a ceramic material, using the same material for the base of the base member and for the lid member is preferable in order to reduce the generation of thermal stress.

The bond 50 bonds the base member 30 and the lid member 40 to each other, and seals the internal space 39. The bond 50 is provided in the form of a frame along the entire periphery of the flange 43 of the lid member 40. The bond 50 is sandwiched between the lower face of the flange 43 of the lid member 40 and the upper face 31A of the base member 30. The bond 50 is made of an insulating material. The bond 50 is made of, for example, an organic adhesive containing an epoxy, vinyl, acrylic, urethane, or silicone resin. The material of the bond 50 is not limited to an organic adhesive. Alternatively, the bond 50 may be made of an inorganic adhesive such as a silicon-based adhesive containing water glass or a calcium-based adhesive containing cement. The bond 50 may be made of a low-melting-point glass such as a lead borate-based or tin phosphate-based glass, or may be made of a eutectic alloy such as lead-tin (Pb—Sn), gold-tin (Au—Sn), silicon-gold (Si—Au), silicon-aluminum (Si—Al), gold-germanium (Au—Ge), aluminum-germanium (Al—Ge), gold-indium (Au—In), or copper-tin (Cu—Sn).

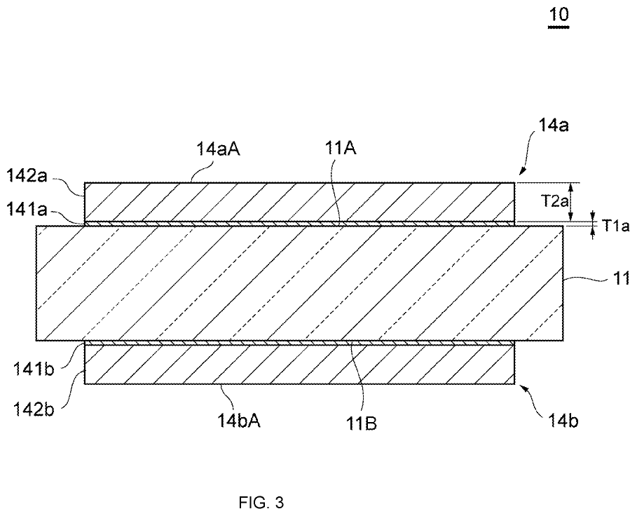

With reference to FIG. 3, the respective configurations of the first excitation electrode 14a and the second excitation electrode 14b according to the first embodiment will now be described. FIG. 3 is a cross-sectional view of the quartz crystal resonator 10 according to the first embodiment.

The first excitation electrode 14a includes a first metal layer 141a and a second metal layer 142a. The first metal layer 141a is disposed on or over the upper face 11A of the quartz crystal element 11. The second metal layer 142a is disposed on or over a side of the first metal layer 141a opposite from the quartz crystal element 11, and defines a surface 14aA of the first excitation electrode 14a. For example, the quartz crystal element 11, the first metal layer 141a, and the second metal layer 142a are stacked in this order, the first metal layer 141a is in contact with the quartz crystal element 11, and the second metal layer 142a is in contact with the first metal layer 141a. The first metal layer 141a corresponds to the base layer mentioned above, and the second metal layer 142a corresponds to the surface layer mentioned above.

The difference in thermal expansion coefficient between the first metal layer 141a and the quartz crystal element 11 is less than the difference in thermal expansion coefficient between the second metal layer 142a and the quartz crystal element 11. This configuration reduces the film stress of the first excitation electrode 14a. One of the first and second metal layers 141a and 142a may have a thermal expansion coefficient greater than the thermal expansion coefficient of the quartz crystal element 11, and the other may have a thermal expansion coefficient less than the thermal expansion coefficient of the quartz crystal element 11. This configuration reduces the film stress of the first excitation electrode 14a.

An element constituting the first metal layer 141a diffuses into the second metal layer 142a, and precipitates at the surface 14aA of the first excitation electrode 14a. The constituent element of the first metal layer 141a that has precipitated at the surface becomes oxidized, which causes a change in the mass of the first excitation electrode 14a. This can lead to frequency drift of the quartz crystal resonator 10. At the surface 14aA of the first excitation electrode 14a, the elemental ratio of a constituent element of the second metal layer 142a is greater than or equal to 99.5% and less than or equal to 100%. Making the elemental ratio of the constituent element of the second metal layer 142a greater than or equal to 99.5% reduces the frequency drift of the quartz crystal resonator 10 caused by oxidation of the surface-precipitated constituent element of the first metal layer 141a.

The second metal layer 142a has a thickness T2a greater than a thickness T1a of the first metal layer 141a (T1a<T2a). Making the thickness T2a greater than the thickness T1a helps to reduce the amount of the constituent element of the first metal layer 141a that diffuses into the second metal layer 142a, and also extend the diffusion path through which the constituent element of the first metal layer 141a diffuses within the second metal layer 142a. This reduces precipitation of the constituent element of the first metal layer 141a at the surface 14aA of the first excitation electrode 14a. This also leads to a reduced amount of the constituent element of the first metal layer 141a that is oxidized at the side faces of the first excitation electrode 14a.

When the first metal layer 141a is made of chromium (Cr) and the second metal layer 142a is made of gold (Au), the thickness T1a of the first metal layer 141a is preferably less than or equal to 0.5 nm. As a result of the above-mentioned configuration, there is not enough chromium available in the first metal layer 141a to sufficiently diffuse through the gold grain boundaries in the second metal layer 142a. This helps to sufficiently reduce the amount of chromium precipitating at the surface 14aA of the first excitation electrode 14a. Further, the thickness T2a of the second metal layer 142a is preferably greater than or equal to 30 nm, and more preferably greater than or equal to 50 nm. This results in an extended diffusion path through which chromium diffuses within the second metal layer 142a. This in turn helps to sufficiently reduce the amount of chromium reaching and precipitating at the surface 14aA of the first excitation electrode 14a.

When the material of the first metal layer 141a is chromium (Cr) and the material of the second metal layer 142a is gold (Au), in order to ensure sufficient adhesion of the first excitation electrode 14a to the quartz crystal element 11, the thickness T1a of the first metal layer 141a is preferably greater than or equal to 0.3 nm, and more preferably greater than or equal to 0.4 nm. To mitigate an increase in materials cost and a decrease in production efficiency, the thickness T2a of the second metal layer 142a is preferably less than or equal to 160 nm, more preferably less than or equal to 120 nm, and even more preferably less than or equal to 100 nm.

When the material of the first metal layer 141a is chromium (Cr) and the material of the second metal layer 142a is gold (Au), the film thickness ratio of the thickness T1a of the first metal layer 141a to the thickness T2a of the second metal layer 142a is preferably greater than or equal to 0.2% and less than or equal to 1.7%, and more preferably greater than or equal to 0.3% and less than or equal to 1.0%. Further, the weight ratio of the weight of the first metal layer 141a to the weight of the second metal layer 142a is preferably greater than or equal to 0.05% and less than or equal to 0.7%, and more preferably greater than or equal to 0.1% and less than or equal to 0.4%.

When the first metal layer 141a is made of a titanium-tungsten alloy (WTi) and the second metal layer 142a is made of gold (Au), the thickness T1a of the first metal layer 141a is preferably less than or equal to 2.0 nm, more preferably less than or equal to 1.0 nm, and even more preferably less than or equal to 0.5 nm. As a result of the above-mentioned configuration, there are not enough titanium and tungsten available in the first metal layer 141a to sufficiently diffuse through the gold grain boundaries in the second metal layer 142a. This helps to sufficiently reduce the amount of titanium and tungsten precipitating at the surface 14aA of the first excitation electrode 14a. Further, the thickness T2a of the second metal layer 142a is preferably greater than or equal to 30 nm, and more preferably greater than or equal to 50 nm. This results in an extended diffusion path through which titanium and tungsten diffuse within the second metal layer 142a. This in turn helps to sufficiently reduce the amount of titanium and tungsten reaching and precipitating at the surface 14aA of the first excitation electrode 14a.

When the material of the first metal layer 141a is a titanium-tungsten alloy (WTi) and the material of the second metal layer 142a is gold (Au), in order to ensure sufficient adhesion of the first excitation electrode 14a to the quartz crystal element 11, the thickness T1a of the first metal layer 141a is preferably greater than or equal to 0.3 nm, and more preferably greater than or equal to 0.4 nm. To mitigate an increase in materials cost and a decrease in production efficiency, the thickness T2a of the second metal layer 142a is preferably less than or equal to 160 nm, more preferably less than or equal to 120 nm, and even more preferably less than or equal to 100 nm.

When the first metal layer 141a is made of a titanium-tungsten alloy (WTi) and the second metal layer 142a is made of gold (Au), the film thickness ratio of the thickness T1a of the first metal layer 141a to the thickness T2a of the second metal layer 142a is preferably greater than or equal to 0.2% and less than or equal to 6.7%, and more preferably greater than or equal to 0.3% and less than or equal to 2.0%. Further, the weight ratio of the weight of the first metal layer 141a to the weight of the second metal layer 142a is preferably greater than or equal to 0.1% and less than or equal to 5.0%, and more preferably greater than or equal to 0.2% and less than or equal to 1.5%.

The second excitation electrode 14b includes a first metal layer 141b and a second metal layer 142b. The first metal layer 141b is disposed on the lower face 11B of the quartz crystal element 11. The second metal layer 142b is disposed on the first metal layer 141b, and located at a surface 14bA of the second excitation electrode 14b. The first metal layer 141b corresponds to the base layer mentioned above, and the second metal layer 142b corresponds to the surface layer mentioned above.

At the surface 14bA of the second excitation electrode 14b, the elemental ratio of an element constituting the second metal layer 142b is greater than or equal to 99.5% and less than or equal to 100%. The relationship between the first and second metal layers 141b and 142b of the second excitation electrode 14b in terms of material, thermal expansion coefficient, thickness, film thickness ratio, and weight ratio is identical or similar to the relationship between the first and second metal layers 141a and 142a of the first excitation electrode 14a in terms of material, thermal expansion coefficient, thickness, film thickness ratio, and weight ratio.

With regard to the condition mentioned above with reference to the present embodiment, that is, the condition that the excitation electrode has a first metal layer and a second metal layer and that the elemental ratio, at the surface of the excitation electrode, of the element constituting the second metal layer is greater than or equal to 99.5% and less than or equal to 100%, the condition is satisfied for both the first excitation electrode and the second excitation electrode. This, however, is not intended to be limiting. It may suffice that the above condition on the elemental ratio be satisfied for at least one of the first excitation electrode or the second excitation electrode. Likewise, with regard to the condition that the difference in thermal expansion coefficient between the first metal layer and the quartz crystal element is less than the difference in thermal expansion coefficient between the second metal layer and the quartz crystal element, the condition is preferably satisfied for at least one of the first excitation electrode or the second excitation electrode. Likewise, with regard to the condition that the thickness of the second metal layer is greater than the thickness of the first metal layer, the condition is preferably satisfied for at least one of the first excitation electrode or the second excitation electrode.

When the first metal layer is made of chromium and the second metal layer is made of gold in at least one of the first excitation electrode or the second excitation electrode, the thickness of the first metal layer is preferably greater than or equal to 0.3 nm and less than or equal to 0.5 nm, and preferably greater than or equal to 0.4 nm and less than or equal to 0.5 nm. The thickness of the second metal layer is preferably greater than or equal to 30 nm and less than or equal to 160 nm, and more preferably greater than or equal to 30 nm and less than or equal to 120 nm. The film thickness ratio of the thickness of the first metal layer to the thickness of the second metal layer is preferably greater than or equal to 0.2% and less than or equal to 1.7%, and more preferably greater than or equal to 0.3% and less than or equal to 1.0%. The weight ratio of the weight of the first metal layer to the weight of the second metal layer is preferably greater than or equal to 0.05% and less than or equal to 0.7%, and more preferably greater than or equal to 0.1% and less than or equal to 0.4%. As described above, preferred numerical ranges exist for the thickness of the first metal layer, the thickness of the second metal layer, the film thickness ratio of the thickness of the first metal layer to the thickness of the second metal layer, and the weight ratio of the weight of the first metal layer to the weight of the second metal layer. In this regard, these preferred numerical ranges preferably hold for both the first and second excitation electrodes, rather than for only one of the first and second excitation electrodes.

When the first metal layer is made of a titanium-tungsten alloy and the second metal layer is made of gold in at least one of the first excitation electrode or the second excitation electrode, the thickness of the first metal layer is preferably greater than or equal to 0.3 nm and less than or equal to 2.0 nm, more preferably greater than or equal to 0.4 nm and less than or equal to 1.0 nm, and even more preferably greater than or equal to 0.4 nm and less than or equal to 0.5 nm. The thickness of the second metal layer is preferably greater than or equal to 30 nm and less than or equal to 160 nm, and more preferably greater than or equal to 50 nm and less than or equal to 120 nm. The film thickness ratio of the thickness of the first metal layer to the thickness of the second metal layer is preferably greater than or equal to 0.2% and less than or equal to 6.7%, and more preferably greater than or equal to 0.3% and less than or equal to 2.0%. The weight ratio of the weight of the first metal layer to the weight of the second metal layer is preferably greater than or equal to 0.1% and less than or equal to 5.0%, and more preferably greater than or equal to 0.2% and less than or equal to 1.5%. As described above, preferred numerical ranges exist for the thickness of the first metal layer, the thickness of the second metal layer, the film thickness ratio of the thickness of the first metal layer to the thickness of the second metal layer, and the weight ratio of the weight of the first metal layer to the weight of the second metal layer. In this regard, these preferred numerical ranges preferably hold for both the first and second excitation electrodes, rather than for only one of the first and second excitation electrodes.

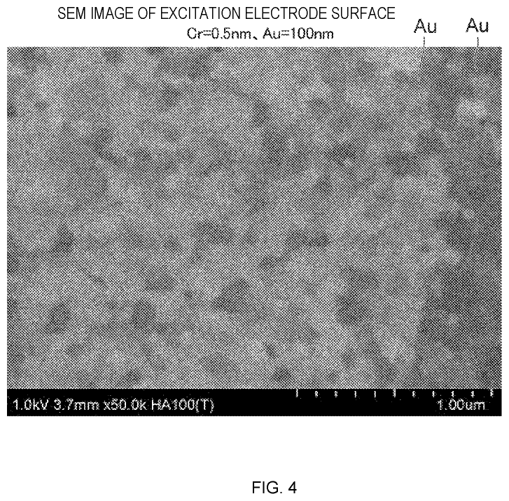

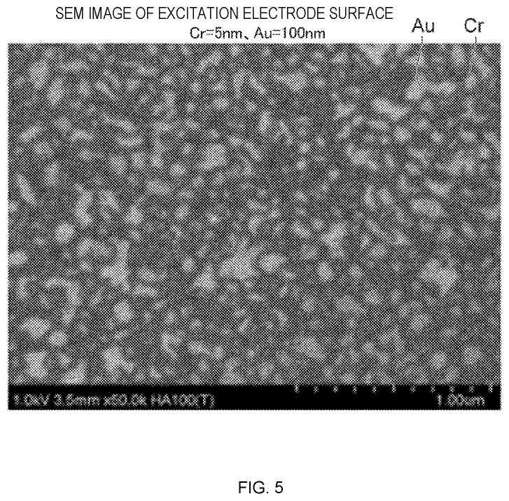

The condition of an excitation electrode surface will now be described with reference to FIGS. 4 and 5. FIG. 4 is an SEM image of an excitation electrode surface according to an example. FIG. 5 is an SEM image of an excitation electrode surface according to a comparative example. The SEM image in FIG. 4 is taken at the surface of an excitation electrode. The excitation electrode in this case includes a first metal layer made of chromium and having a thickness of 0.5 nm, and a second metal layer made of gold and having a thickness of 100 nm. The SEM image in FIG. 5 is taken at the surface of an excitation electrode. The excitation electrode in this case includes a first metal layer made of chromium and having a thickness of 5 nm, and a second metal layer made of gold and having a thickness of 100 nm.

As illustrated in FIG. 4, when the first metal layer made of chromium has a thickness of 0.5 nm, gold grain boundaries are observed at the surface of the excitation electrode. However, substantially no chromium diffusing through the gold grain boundaries is observed at the surface. In other words, it is found that when the first metal layer made of chromium has a thickness of 0.5 nm, substantially no surface precipitation of chromium occurs. In contrast, it is confirmed that as illustrated in FIG. 5, when the first metal layer made of chromium has a thickness of 5 nm, chromium precipitates along the gold grain boundaries at the surface of the excitation electrode.

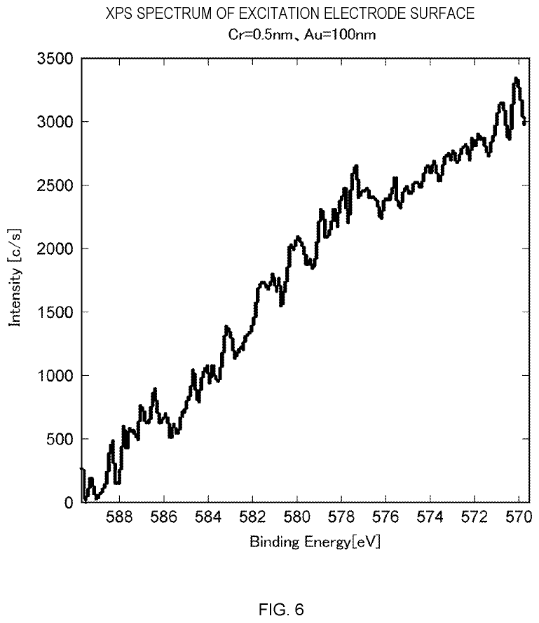

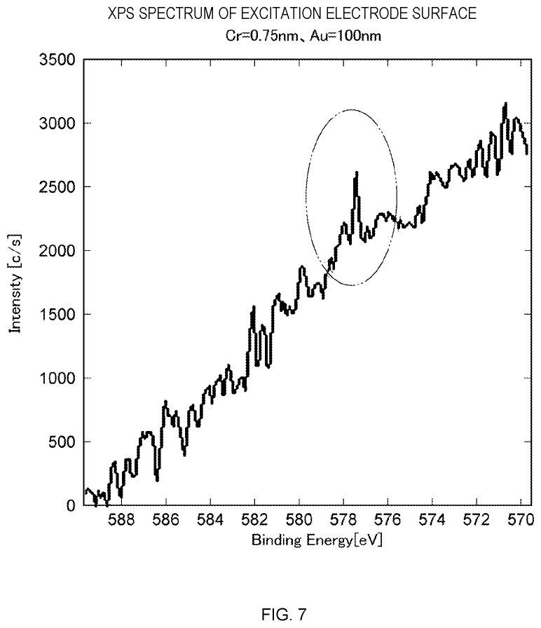

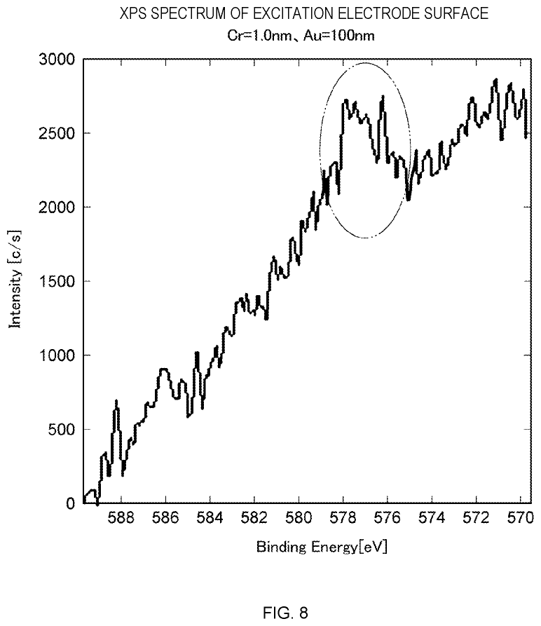

With reference to FIGS. 6 to 8, the results of elemental analysis of an excitation electrode surface through X-ray photoelectron spectroscopy (XPS) will now be described. FIG. 6 is a graph representing the XPS measurements of an excitation electrode surface according to an example. FIGS. 7 and 8 are graphs each representing the XPS measurements of an excitation electrode surface according to a comparative example. In the graphs in FIGS. 6 to 8, the horizontal axis represents binding energy [eV], and the vertical axis represents intensity [c/s]. The graph in FIG. 6 represents measurements taken at the surface of an excitation electrode. The excitation electrode in this case includes a first metal layer made of chromium and having a thickness of 0.5 nm, and a second metal layer made of gold and having a thickness of 100 nm. The graph in FIG. 7 represents measurements taken at the surface of an excitation electrode. The excitation electrode in this case includes a first metal layer made of chromium and having a thickness of 0.75 nm, and a second metal layer made of gold and having a thickness of 100 nm. The graph in FIG. 8 represents measurements taken at the surface of an excitation electrode. The excitation electrode in this case includes a first metal layer made of chromium and having a thickness of 1.0 nm, and a second metal layer made of gold and having a thickness of 100 nm.

In surface elemental analysis through XPS, the presence of chromium at the surface of the excitation electrode results in the occurrence of a peak at 577 eV in the photoelectron spectrum. The higher the elemental ratio of chromium, the greater the intensity of the 577 eV peak in the photoelectron spectrum. As illustrated in FIG. 6, when the first metal layer made of chromium has a thickness of 0.5 nm, no peak is observed at 577 eV in the photoelectron spectrum, indicating that substantially no chromium is present at the surface of the excitation electrode. As illustrated in FIG. 7, when the first metal layer made of chromium has a thickness of 0.75 nm, a peak occurs at 577 eV in the photoelectron spectrum, indicating the presence of chromium precipitation at the surface of the excitation electrode. As illustrated in FIG. 8, when the first metal layer made of chromium has a thickness of 1.0 nm, the intensity of the peak at 577 eV in the photoelectron spectrum is greater than that when the chromium thickness is 0.75 nm. This indicates that when the chromium thickness is greater than 0.5 nm, the amount of chromium precipitating at the surface of the excitation electrode increases with chromium thickness.

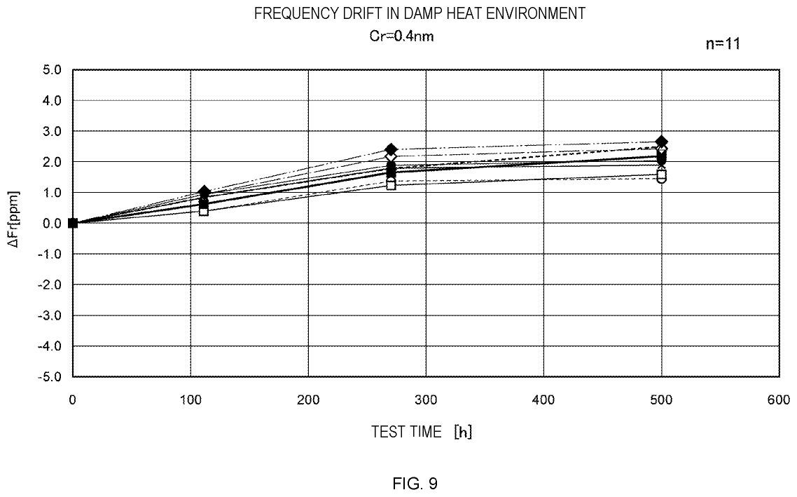

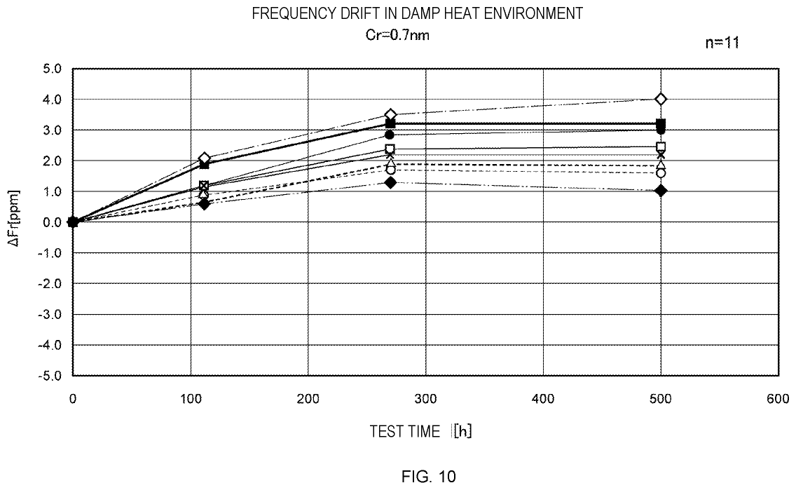

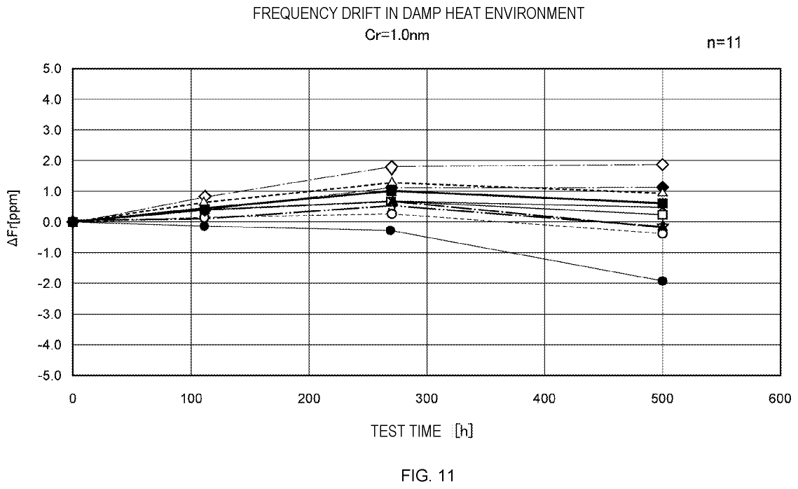

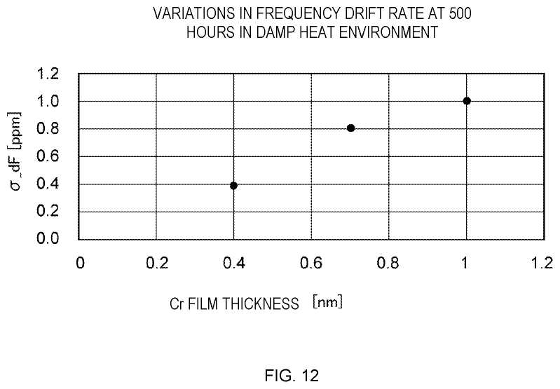

With reference to FIGS. 9 to 12, frequency drift in a damp heat environment will now be described. FIG. 9 is a graph representing frequency drift in a damp heat environment according to an example. FIGS. 10 and 11 are graphs each representing frequency drift in a damp heat environment according to a comparative example. FIG. 12 is a graph representing variations in frequency drift rate in a damp heat environment. In FIGS. 9 to 11, the horizontal axis represents the time (test time [h]) for which quartz crystal resonator units are left in the damp heat environment, and the vertical axis represents frequency drift rate (ΔFr [ppm]). In FIG. 12, the horizontal axis represents the thickness of the first metal layer made of chromium (Cr film thickness [nm]), and the vertical axis represents variations in frequency drift rate (σ_dF [ppm]) of quartz crystal resonator units left in the damp heat environment for 500 hours.

The graphs in FIGS. 9 to 12 represent data obtained by allowing quartz crystal resonator units to stand in a temperature- and humidity-controlled oven set to a temperature of 85 °C and a relative humidity of 85% RH, taking the quartz crystal resonator units out of the temperature-and humidity-controlled oven at 110 hours, 270 hours, and 500 hours, and measuring the frequencies of the quartz crystal resonator units. The frequency drift rate ΔFr is calculated according to the following equation:

ΔFr=(Fr−Fr0)/Fr0,
where Fr denotes the frequency of each quartz crystal resonator unit at each test time, and Fr0 denotes the frequency of the quartz crystal resonator unit before being placed in the temperature-and humidity-controlled oven.

When the frequency of the quartz crystal resonator unit increases, the value of ΔFr becomes positive, and when the frequency of the quartz crystal resonator unit decreases, the value of ΔFr becomes negative. The number of samples of quartz crystal resonator units is 11 (n=11) for each condition.

As illustrated in FIG. 9, when the first metal layer made of chromium has a thickness of 0.4 nm, ΔFr increases over time and has a positive value for all samples within the test time range up to 500 hours. At each test time, the variations in ΔFr in FIG. 9, where the chromium thickness is greater than or equal to 0.3 nm and less than or equal to 0.5 nm, are less than the variations in ΔFr in FIGS. 10 and 11, where the chromium thickness is greater than 0.5 nm.

As illustrated in FIG. 10, when the first metal layer made of chromium has a thickness of 0.7 nm, ΔFr increases over time and has a positive value for all samples within the test time range up to 270 hours. At 500 hours of test time, all samples have positive values of ΔFr. However, a subset of the samples exhibit decreased ΔFr at 500 hours of test time relative to ΔFr at 270 hours of test time.

As illustrated in FIG. 11, when the first metal layer made of chromium has a thickness of 1.0 nm, for many samples, ΔFr at 270 hours of test time exhibits an increase relative to ΔFr at 110 hours of test time, and has a positive value. However, for a subset of the samples, ΔFr at 270 hours of test time exhibits a decrease relative to ΔFr at 110 hours of test time, and has a negative value. At 500 hours of test time, ΔFr exhibits a decrease relative to ΔFr at 270 hours of test time for a number of samples even greater than the number of samples for which a decreasing trend in ΔFr is observed at 270 hours of test time.

From the values of ΔFr at 500 hours of test time in FIGS. 9 to 11, a standard deviation σ_dF, which represents variations in frequency drift rate, is calculated, and the graph in FIG. 12 is created. As illustrated in FIG. 12, as the Cr film thickness decreases, σ dF decreases, and the reliability of the quartz crystal resonator unit improves. For example, setting the Cr film thickness to less than or equal to 0.5 nm allows σ dF to be kept to a value less than or equal to 0.5 ppm.

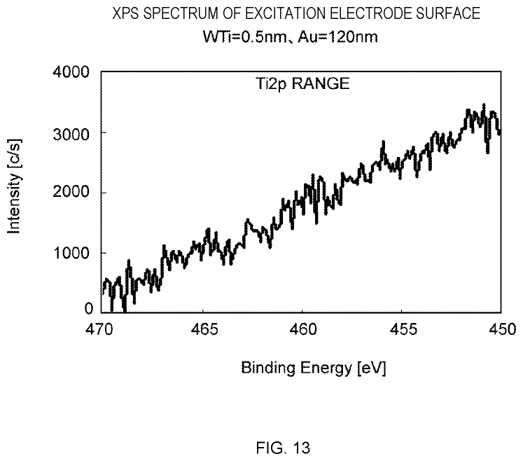

Reference will now be made to FIGS. 13 to 20 to describe, for a case where the first metal layer is made of a titanium-tungsten alloy (WTi) and the second metal layer is made of gold (Au), how the surface condition changes as the thickness of the first metal layer is varied. FIGS. 13 to 20 are graphs representing the XPS measurements of the excitation electrode surface.

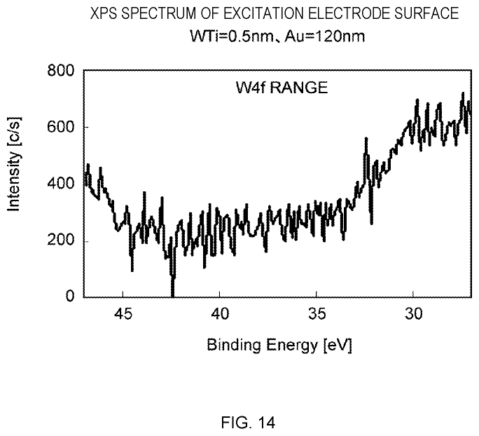

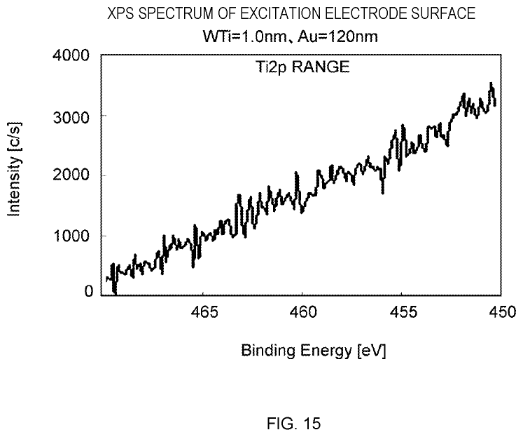

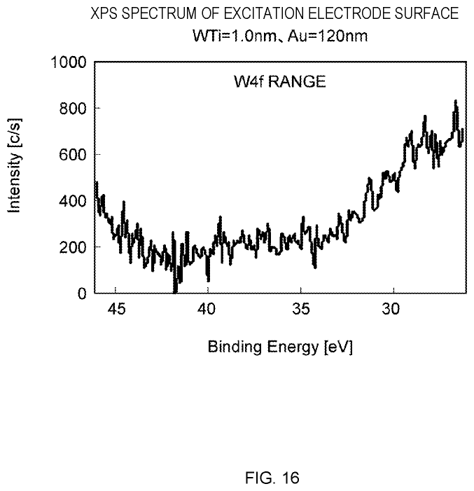

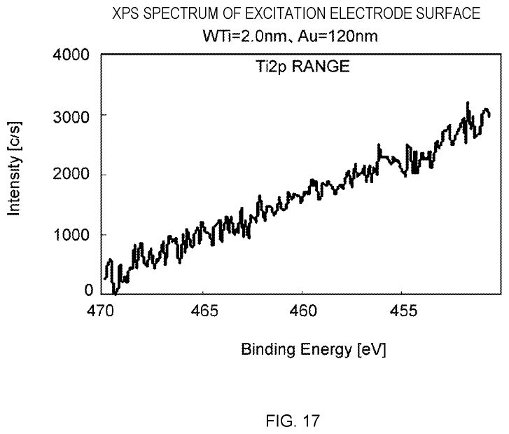

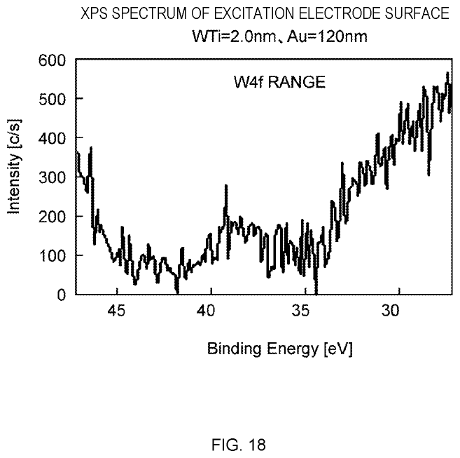

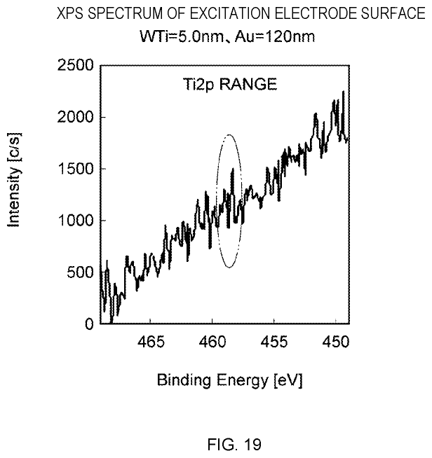

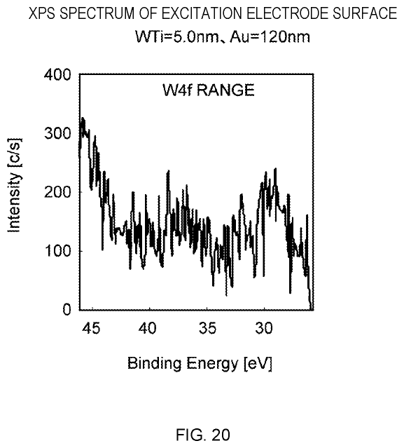

FIGS. 13 and 14 are graphs each representing the results of elemental analysis of the excitation electrode surface through XPS when the first metal layer has a thickness of 0.5 nm. FIGS. 15 and 16 are graphs each representing the results of elemental analysis of the excitation electrode surface through XPS when the first metal layer has a thickness of 1.0 nm. FIGS. 17 and 18 are graphs each representing the results of elemental analysis of the excitation electrode surface through XPS when the first metal layer has a thickness of 2.0 nm. FIGS. 19 and 20 are graphs each representing the results of elemental analysis of the excitation electrode surface through XPS when the first metal layer has a thickness of 5.0 nm. The respective second metal layers of the excitation electrodes measured in FIGS. 13 to 20 have the same thickness of 120 nm.

In the graphs in FIGS. 13, 15, 17, and 19, the horizontal axis represents binding energy [eV] in the vicinity of the binding energy of photoelectrons (Ti2p) in the 2p orbital of titanium, and the vertical axis represents intensity [c/s]. In the graphs in FIGS. 14, 16, 18, and 20, the horizontal axis represents binding energy [eV] in the vicinity of the binding energy of photoelectrons (W4f) in the 4f orbital of tungsten, and the vertical axis represents intensity [c/s].

A comparison between the graphs in FIGS. 13, 15, 17, and 19 reveals that, for the first metal layer thicknesses of 0.5 nm, 1.0 nm, and 2.0 nm, no Ti2p peak is observed, indicating that substantially no titanium is present at the surface of the excitation electrode. However, for the first metal layer thickness of 5.0 nm, a Ti2p peak is observed at 455 nm to 460 nm, indicating the presence of titanium precipitating at the surface of the excitation electrode.

A comparison between the graphs in FIGS. 14, 16, 18, and 20 reveals that, for the first metal layer thicknesses of 0.5 nm, 1.0 nm, and 2.0 nm, no W4f peak is observed, indicating that substantially no tungsten is present at the surface of the excitation electrode. However, for the first metal layer thickness of 5.0 nm, a W4f peak is observed at 35 nm to 40 nm, indicating the presence of tungsten precipitating at the surface of the excitation electrode.

Therefore, when the first metal layer has a thickness less than or equal to 2.0 nm, neither titanium nor tungsten of the titanium-tungsten alloy constituting the first metal layer precipitates at the surface of the excitation electrode. This helps to mitigate frequency drift caused by oxidation of titanium and tungsten.

As described above, according to the present embodiment, the quartz crystal resonator 10 includes the first excitation electrode 14a disposed on or over the upper face 11A of the quartz crystal element 11. The first excitation electrode 14a includes the first metal layer 141a disposed on or over the quartz crystal element 11, and the second metal layer 142a disposed on or over a side of the first metal layer 141a opposite from the quartz crystal element 11. The second metal layer 142a is made of a material that is more resistant to oxidation than the material of the first metal layer 141a. At the surface 14aA of the first excitation electrode 14a, the elemental ratio of an element constituting the second metal layer 142a is greater than or equal to 99.5% and less than or equal to 100%.

The above-mentioned configuration reduces oxidation of the constituent element of the first metal layer 141a that has precipitated at the surface 14aA of the first excitation electrode 14a. This therefore helps to reduce frequency drift of the quartz crystal resonator 10.

In an aspect of the present embodiment, the thickness T2a of the second metal layer 142a is greater than the thickness T1a of the first metal layer 141a.

The above-mentioned configuration helps to reduce the amount of the constituent element of the first metal layer 141a that diffuses into the second metal layer 142a, and also extend the diffusion path through which the constituent element of the first metal layer 141a diffuses within the second metal layer 142a. This reduces precipitation of the constituent element of the first metal layer 141a at the surface 14aA of the first excitation electrode 14a. Further, the area of the first metal layer 141a exposed at the side faces of the first excitation electrode 14a decreases. This reduces the amount of the constituent element of the first metal layer 141a that is oxidized at the side faces of the first excitation electrode 14a.

In an aspect of the present embodiment, the difference in thermal expansion coefficient between the first metal layer 141a and the quartz crystal element 11 is less than the difference in thermal expansion coefficient between the second metal layer 142a and the quartz crystal element 11.

The above-mentioned configuration reduces the film stress of the first excitation electrode 14a. This helps to reduce distortion of the quartz crystal element 11 caused by the film stress of the first excitation electrode 14a, and consequently reduce fluctuations in vibration characteristics caused by distortion of the quartz crystal element 11.

In an aspect of the present embodiment, the material of the first metal layer 141a is chromium (Cr), the material of the second metal layer 142a is gold (Au), and the thickness T1a of the first metal layer 141a is greater than or equal to 0.3 nm and less than or equal to 0.5 nm.

According to the above-mentioned configuration, the film thickness of chromium is greater than or equal to 0.3 nm. This helps to ensure sufficient adhesion of the first excitation electrode 14a to the quartz crystal element 11. Further, the film thickness of chromium is less than or equal to 0.5 nm. As a result, there is not enough chromium available in the first metal layer 141a to sufficiently diffuse through the gold grain boundaries in the second metal layer 142a. This helps to sufficiently reduce the amount of chromium precipitating at the surface 14aA of the first excitation electrode 14a.

In an aspect of the present embodiment, the material of the first metal layer 141a is chromium (Cr), the material of the second metal layer 142a is gold (Au), and the thickness T2a of the second metal layer 142a is greater than or equal to 30 nm and less than or equal to 160 nm.

In an aspect of the present embodiment, the material of the first metal layer 141a is chromium (Cr), the material of the second metal layer 142a is gold (Au), and the thickness T2a of the second metal layer 142a is greater than or equal to 30 nm and less than or equal to 120 nm.

According to the above-mentioned configuration, making the film thickness of gold greater than or equal to 30 nm results in an extended diffusion path through which chromium diffuses within the second metal layer 142a. This helps to sufficiently reduce the amount of chromium reaching and precipitating at the surface 14aA of the first excitation electrode 14a. Making the film thickness of gold less than or equal to 160 nm helps to mitigate an increase in materials cost, and also mitigate a decrease in production efficiency. Making the film thickness of gold less than or equal to 120 nm helps to further mitigate an increase in materials cost, and also further mitigate a decrease in production efficiency.

In an aspect of the present embodiment, the material of the first metal layer 141a is a titanium-tungsten alloy (WTi), the material of the second metal layer 142a is gold (Au), and the thickness T1a of the first metal layer 141a is greater than or equal to 0.3 nm and less than or equal to 2.0 nm.

According to the above-mentioned configuration, the film thickness of the titanium-tungsten alloy is greater than or equal to 0.3 nm. This helps to ensure sufficient adhesion of the first excitation electrode 14a to the quartz crystal element 11. Further, the film thickness of the titanium-tungsten alloy is less than or equal to 2.0 nm. As a result, there is not enough titanium available in the first metal layer 141a to sufficiently diffuse through the gold grain boundaries in the second metal layer 142a. This helps to sufficiently reduce the amount of titanium precipitating at the surface 14aA of the first excitation electrode 14a.

In an aspect of the present embodiment, the material of the first metal layer 141a is a titanium-tungsten alloy (WTi), the material of the second metal layer 142a is gold (Au), and the thickness T2a of the second metal layer 142a is greater than or equal to 30 nm and less than or equal to 160 nm.

In an aspect of the present embodiment, the material of the first metal layer 141a is a titanium-tungsten alloy (WTi), the material of the second metal layer 142a is gold (Au), and the thickness T2a of the second metal layer 142a is greater than or equal to 30 nm and less than or equal to 120 nm.

According to the above-mentioned configuration, making the film thickness of gold greater than or equal to 30 nm results in an extended diffusion path through which titanium and tungsten diffuse within the second metal layer 142a. This helps to sufficiently reduce the amount of titanium and tungsten reaching and precipitating at the surface 14aA of the first excitation electrode 14a. Making the film thickness of gold less than or equal to 160 nm helps to mitigate an increase in materials cost, and also mitigate a decrease in production efficiency. Making the film thickness of gold less than or equal to 120 nm helps to further mitigate an increase in materials cost, and also further mitigate a decrease in production efficiency.

According to an embodiment of the present disclosure, an excitation electrode may further include another metal layer between the quartz crystal element and the first metal layer. Further, according to an embodiment of the present disclosure, an excitation electrode may further include a third metal layer between the first metal layer and the second metal layer. When the third metal layer is made of a material that is less resistant to oxidation than the material of the second metal layer, the thickness of the second metal layer is preferably greater than the thickness of the third metal layer, and more preferably greater than the sum of the thickness of the first metal layer and the thickness of the third metal layer. This helps to reduce the amount of the constituent element of each of the first and third metal layers that diffuses into the second metal layer, and extend the diffusion path through which the constituent element of each of the first and third metal layers diffuses within the second metal layer.

When an excitation electrode has a third metal layer disposed between the first metal layer and the second metal layer, the difference in thermal expansion coefficient between the first metal layer and the quartz crystal element is preferably less than the difference in thermal expansion coefficient between the third metal layer and the quartz crystal element, and the difference in thermal expansion coefficient between the third metal layer and the quartz crystal element is preferably less than the difference in thermal expansion coefficient between the second metal layer and the quartz crystal element. The above-mentioned configuration reduces the film stress of the excitation electrode. This helps to reduce distortion of the quartz crystal element caused by such film stress of the excitation electrode, and consequently reduce fluctuations in vibration characteristics caused by distortion of the quartz crystal element. Of the first, second, and third metal layers, at least one metal layer may have a thermal expansion coefficient greater than the thermal expansion coefficient of the quartz crystal element, and at least one metal layer may have a thermal expansion coefficient less than the thermal expansion coefficient of the quartz crystal element. The above-mentioned configuration reduces the film stress of the excitation electrode. This helps to reduce distortion of the quartz crystal element caused by such film stress of the excitation electrode, and consequently reduce fluctuations in vibration characteristics caused by distortion of the quartz crystal element.

When the third metal layer is made of chromium, the thickness of the third metal layer is preferably greater than or equal to 0.3 nm and less than or equal to 0.5 nm. Making the thickness of the third metal layer greater than or equal to 0.3 nm helps to ensure sufficient adhesion of the third metal layer to the first metal layer, and also ensure sufficient adhesion of the third metal layer to the second metal layer. Making the thickness of the third metal layer less than or equal to 0.5 nm helps to ensure that there is not enough chromium available in the third metal layer to sufficiently diffuse into the second metal layer. This makes it possible to sufficiently reduce the amount of precipitation, at the surface of the excitation electrode, of chromium originating from the third metal layer.

An excitation electrode may further include, in addition to the third metal layer, at least one metal layer between the first metal layer and the second metal layer. The magnitude relationship between the thickness of the at least one metal layer and the respective thicknesses of the first and second metal layers may be identical or similar to the magnitude relationship between the thickness of the third metal layer and the respective thicknesses of the first and second metal layers. The magnitude relationship between the thermal expansion coefficient of the at least one metal layer and the respective thermal expansion coefficients of the first and second metal layers may be identical or similar to the magnitude relationship between the thermal expansion coefficient of the third metal layer and the respective thermal expansion coefficients of the first and second metal layers.

Although the foregoing description is directed to an example of a quartz crystal resonator including a quartz crystal element as a piezoelectric element, such a piezoelectric resonator is not limited to that mentioned above. Suitable examples of the piezoelectric element for use in the piezoelectric resonator unit according to the present embodiment may include piezoelectric ceramic materials such as lead zirconate titanate (PZT) and aluminum nitride, and piezoelectric single crystals such as lithium niobate and lithium tantalate. However, the piezoelectric element is not limited to those mentioned above, but any suitable piezoelectric element may be selected as appropriate.

The embodiments according to the present disclosure may be applied, without particular limitation, to any suitable devices configured to perform electromechanical energy conversion based on the piezoelectric effect, such as timing devices, sounding devices, oscillators, and load sensors.

As described above, an aspect of the present disclosure makes it possible to provide a piezoelectric resonator configured to reduce frequency drift.

The embodiments described above are intended to facilitate understanding of the present disclosure, and are not to be construed as limiting the present disclosure. The present disclosure may be changed or modified without departing from the spirit and scope thereof, and the present disclosure also includes equivalents thereof. That is, embodiments and/or modifications with suitable design variations made by those skilled in the art also fall within the scope of the present disclosure as long as the resulting embodiments and/or modifications include the characteristic features of the present disclosure. For example, individual elements included in such embodiments and/or modifications, and their associated arrangements, materials, conditions, shapes, sizes, or other specific details are not limited to those illustrated but may be changed as appropriate. The embodiments and modifications are provided for illustrative purposes only, and partial substitutions or combinations of structural features described in different embodiments and/or modifications are possible. Such substitutions or combinations also fall within the scope of the present disclosure as long as the resulting embodiments and modifications include the characteristic features of the present disclosure.

### REFERENCE SIGNS LIST

1 quartz crystal resonator unit
10 quartz crystal resonator
30 base member
40 lid member
50 bond
11 quartz crystal element
11A upper face
11B lower face
14a first excitation electrode
14b second excitation electrode
141a, 141b first metal layer
142a, 142b second metal layer
15a first extended electrode
15b second extended electrode
16a first connection electrode
16b second connection electrode

1. A piezoelectric resonator comprising:
a piezoelectric element; and
an excitation electrode disposed on or over a major face of the piezoelectric element, the excitation electrode including:
a first metal layer disposed on or over the piezoelectric element; and
a second metal layer disposed on or over a side of the first metal layer opposite from the piezoelectric element,
wherein the second metal layer is made of a material that is more resistant to oxidation than a material of the first metal layer, and
wherein at a surface of the excitation electrode, an elemental ratio of an element constituting the second metal layer is greater than or equal to 99.5% and less than or equal to 100%.

2. The piezoelectric resonator according to claim 1, wherein the second metal layer has a thickness greater than a thickness of the first metal layer.

3. The piezoelectric resonator according to claim 1, wherein a difference in thermal expansion coefficient between the first metal layer and the piezoelectric element is less than a difference in thermal expansion coefficient between the second metal layer and the piezoelectric element.

4. The piezoelectric resonator according to claim 1,
wherein the material of the first metal layer is chromium, and
wherein the material of the second metal layer is gold.

5. The piezoelectric resonator according to claim 4, wherein the first metal layer has a thickness greater than or equal to 0.3 nm and less than or equal to 0.5 nm.

6. The piezoelectric resonator according to claim 1,
wherein the material of the first metal layer is a titanium-tungsten alloy, and
wherein the material of the second metal layer is gold.

7. The piezoelectric resonator according to claim 6, wherein the first metal layer has a thickness greater than or equal to 0.3 nm and less than or equal to 2.0 nm.

8. The piezoelectric resonator according to claim 6, wherein a ratio of a thickness of the first metal layer to a thickness of the second metal layer is greater than or equal to 0.2% and less than or equal to 6.7%.

9. The piezoelectric resonator according to claim 6, wherein a ratio of a weight of the first metal layer to a weight of the second metal layer is greater than or equal to 0.1% and less than or equal to 5.0%.

10. The piezoelectric resonator according to claim 4, wherein the second metal layer has a thickness greater than or equal to 30 nm and less than or equal to 160 nm.

11. The piezoelectric resonator according to claim 4, wherein the second metal layer has a thickness greater than or equal to 30 nm and less than or equal to 120 nm.

12. The piezoelectric resonator according to claim 4, wherein a ratio of a thickness of the first metal layer to a thickness of the second metal layer is greater than or equal to 0.2% and less than or equal to 1.7%.

13. The piezoelectric resonator according to claim 4, wherein a ratio of a weight of the first metal layer to a weight of the second metal layer is greater than or equal to 0.05% and less than or equal to 0.7%.

14. The piezoelectric resonator according to claim 1, wherein the piezoelectric element is a quartz crystal element.

15. The piezoelectric resonator according to claim 14, wherein the quartz crystal element is an AT-cut quartz crystal element.

16. The piezoelectric resonator according to claim 14, wherein a primary vibration mode of the piezoelectric resonator is a thickness shear vibration mode.

17. The piezoelectric resonator according to claim 1, wherein the excitation electrode further includes a third metal layer between the first metal layer and the second metal layer, the third metal layer is made of a material that is less resistant to oxidation than the material of the second metal layer, and a thickness of the second metal layer is greater than a thickness of the third metal layer.

18. The piezoelectric resonator according to claim 17, wherein the third metal layer is made of chromium and has a thickness greater than or equal to 0.3 nm and less than or equal to 0.5 nm.

19. The piezoelectric resonator according to claim 1, wherein the piezoelectric element has a pair of major faces, the excitation electrode is one of a pair of excitation electrodes respectively disposed on or over the pair of major faces, and at a surface of each of the pair of excitation electrodes, the elemental ratio of the element constituting the second metal layer is greater than or equal to 99.5% and less than or equal to 100%.

20. A piezoelectric resonator unit comprising:
the piezoelectric resonator according to claim 1;
a base member to which the piezoelectric resonator is mounted;
a lid member that accommodates the piezoelectric resonator in a space between the lid member and the base member; and
a bond that bonds the base member and the lid member to each other,
wherein the bond is made of an organic adhesive.
